(19) United States
(12) Patent Application Publication
(10) Pub. No.: US 2025/0253147 A1
(43) Pub. Date: Aug. 7, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventor: Kimihiko NAKATANI, Toyama-shi (JP)

(73) Assignee: Kokusai Electric Corporation, Tokyo (JP)

(21) Appl. No.: 19/084,047

(22) Filed: Mar. 19, 2025

Related U.S. Application Data
(63) Continuation of application No. PCT/JP2023/036230, filed on Oct. 4, 2023.

(30) Foreign Application Priority Data
Dec. 9, 2022 (JP) 2022-197488

(51) Int. Cl. H01L 21/02; H01L 21/67

(52) U.S. Cl. CPC H01L 21/02337; H01L 21/02362; H01L 21/67069

(57) ABSTRACT

There is provided a technique that includes (a) providing the substrate on which a first film and a second film covering the first film are formed, replacing a part of a portion of the first film, which is covered by the second film, with a stopper film, and dividing the first film into a first portion and a second portion by the stopper film; and (b) leaving the second portion by removing the first portion which extends from an end surface of the first portion, which is not covered by the second film, to the stopper film.

### CROSS-REFERENCE TO RELATED APPLICATION

This application is a Bypass Continuation Application of PCT International Application No. PCT/JP2023/036230, filed on Oct. 4, 2023, and designating the United States, the international application being based upon and claiming the benefit of priority from Japanese Patent Application No. 2022-197488, filed on Dec. 9, 2022, the entire content of which is incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process of manufacturing a semiconductor device, a portion of a film formed on a surface of a substrate may be etched.

When etching the film on the substrate, it may be difficult to remove a desired portion of the film with a high degree of precision.

### SUMMARY

Some embodiments of the present disclosure provide a technique capable of, when etching a film on a substrate, removing a desired portion of the film with a high degree of precision.

According to embodiments of the present disclosure, there is provided a technique that includes (a) providing the substrate on which a first film and a second film covering the first film are formed, replacing a part of a portion of the first film, which is covered by the second film, with a stopper film, and dividing the first film into a first portion and a second portion by the stopper film; and (b) leaving the second portion by removing the first portion which extends from an end surface of the first portion, which is not covered by the second film, to the stopper film.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is illustrated in a vertical cross-sectional view.

FIG. 2 is a schematic configuration diagram of the vertical process furnace of the substrate processing apparatus suitably used in the embodiments of the present disclosure, in which a portion of the process furnace is illustrated in a cross-sectional view taken along line A-A in FIG. 1.

FIG. 3 is a schematic configuration diagram of a controller of the substrate processing apparatus suitably used in the embodiments of the present disclosure, illustrating a control system of the controller in a block diagram.

FIG. 4 is a diagram illustrating a processing sequence in the embodiments of the present disclosure.

FIG. 5A is a cross-sectional view of a wafer on which a first film, a second film, a third film, and a fourth film are formed in some embodiments of the present disclosure.

FIG. 5B is a perspective view of the wafer in some embodiments of the present disclosure.

FIG. 6A is a cross-sectional view of the wafer processed in a substrate processing process in some embodiments of the present disclosure.

FIG. 6B is a cross-sectional view of a state in which a groove is formed by providing a hard mask on the second film of the wafer from a state of FIG. 6A.

FIG. 6C is a cross-sectional view of a state in which the hard mask is removed from the state of FIG. 6B.

FIG. 7A is a diagram illustrating a process of forming a stopper in the first film of the wafer in some embodiments of the present disclosure, which is a cross-sectional view of a state in which a modified layer is formed on a second end surface of the second film.

FIG. 7B is a cross-sectional view of a state in which the stopper is formed between first end surfaces of the first film from the state of FIG. 7A.

FIG. 7C is a cross-sectional view of a state in which the modified layer on the second end surface of the second film is removed from the state of FIG. 7B.

FIG. 7D is a cross-sectional view of a state in which the groove is re-filled with the second film from the state of FIG. 7C.

FIG. 8A is a cross-sectional view of a state in which a hard mask is formed on the second film in some embodiments of the present disclosure.

FIG. 8B is a cross-sectional view of a state in which the hard mask is removed after a first portion of the first film and the third film are removed from the state of FIG. 8A.

FIG. 8C is a cross-sectional view of a state in which a hard mask is provided on the second film and the stopper is removed from the state of FIG. 8B.

FIG. 8D is a cross-sectional view of a state in which the hard mask is removed from the state of FIG. 8C.

FIG. 9A is a cross-sectional view of the wafer processed in a substrate processing process in other embodiments of the present disclosure.

FIG. 9B is a cross-sectional view of a state in which a recess is formed in the second film of the wafer 200 by providing a hard mask on the second film from a state of FIG. 9A.

FIG. 9C is a cross-sectional view of a state in which the hard mask is removed from the state of FIG. 9B.

FIG. 10 is a cross-sectional view illustrating a process of forming the stopper in the first film of the wafer in the substrate processing process.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Some Embodiments of Present Disclosure

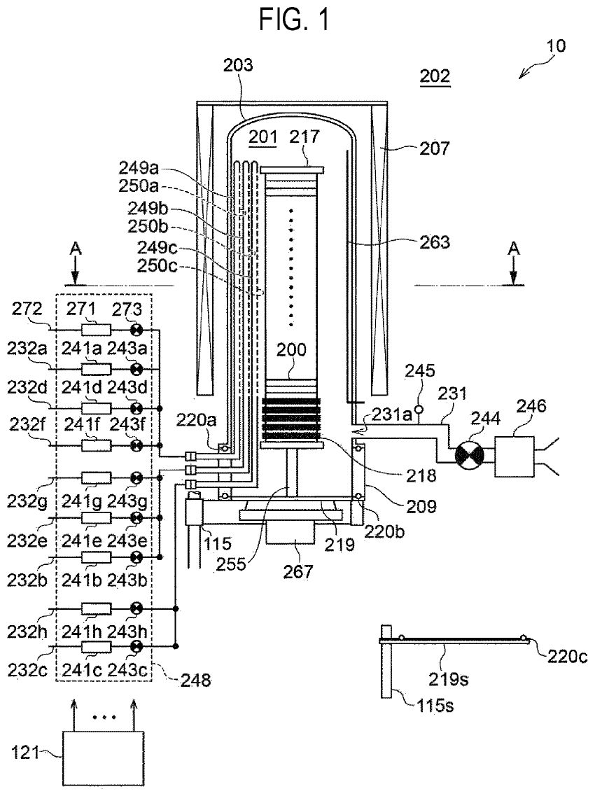

Hereinafter, some embodiments of the present disclosure are mainly described with reference to FIGS. 1 to 9C. The drawings used in the following description are schematic, and dimensional relationships of respective elements, proportions of respective elements, and the like shown in the drawings may not match actual ones. Further, even among the drawings, the dimensional relationships of respective elements, the ratios of respective elements, and the like may not always match. Further, unless particularly specified otherwise, each element is not limited to one in number, and may be provided in a plural number.

### (1) Configuration of Substrate Processing Apparatus

As illustrated in FIG. 1, a process furnace 202 constituting a substrate processing apparatus 10 includes a heater 207 as a temperature regulator (heating part). The heater 207 also functions as an activator (exciter) which activates (excites) a gas with heat.

Inside the heater 207, a reaction tube 203 is disposed concentrically with the heater 207. The reaction tube 203 is formed in a cylindrical shape with an upper end thereof closed and a lower end thereof opened. Below the reaction tube 203, a manifold 209 is disposed concentrically with the reaction tube 203. An O-ring 220a is provided between the manifold 209 and the reaction tube 203. A process container (reaction container) mainly includes the reaction tube 203 and the manifold 209. A process chamber 201 is formed in a cylindrical hollow portion of the process container. The process chamber 201 is configured to be capable of accommodating wafers 200 as substrates. A processing on the wafers 200 is performed in the process chamber 201.

In the process chamber 201, each of nozzles 249a to 249c as first to third suppliers is provided to penetrate through a sidewall of the manifold 209. Gas supply pipes 232a to 232c are connected to the nozzles 249a to 249c, respectively.

In the gas supply pipes 232a to 232c, mass flow controllers (MFCs) 241a to 241c, which are flow rate controllers (flow rate control parts), and valves 243a to 243c, which are opening/closing valves, are provided sequentially from an upstream of a gas flow, respectively. Each of gas supply pipes 232d and 232f is connected to the gas supply pipe 232a at a downstream of the valve 243a. Each of gas supply pipes 232e and 232g is connected to the gas supply pipe 232b at a downstream of the valve 243b. A gas supply pipe 232h is connected to the gas supply pipe 232c at a downstream of the valve 243c. In the gas supply pipes 232d to 232h, MFCs 241d to 241h and valves 243d to 243h are provided sequentially from an upstream of a gas flow, respectively.

In addition, a gas supply pipe 272 is connected to the nozzle 249a. An MFC 271, which is a flow rate controller (flow rate control part), and a valve 273, which is an opening/closing valve, are provided sequentially from an upstream of a gas flow in the gas supply pipe 272. Each of the above-described gas supply pipes 232a, 232d, and 232f is connected to the gas supply pipe 272 at a downstream of the valve 273.

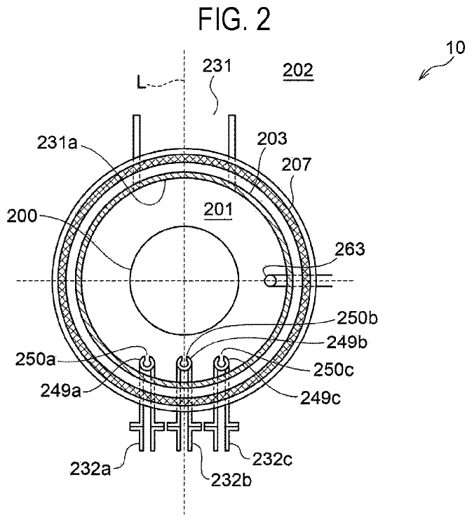

As illustrated in FIG. 2, the nozzles 249a to 249c are provided in an annular space in a plane view between an inner wall of the reaction tube 203 and the wafers 200 to extend upward in an arrangement direction of the wafers 200 along an upper portion of the inner wall of the reaction tube 203 from a lower portion of the inner wall of the reaction tube 203. The nozzles 249a and 249c are disposed to sandwich a straight line L, passing through centers of the nozzle 249b and an exhaust port 231a, from both sides thereof along the inner wall of the reaction tube 203. Gas supply holes 250a to 250c for supplying gases are formed on side surfaces of the nozzles 249a to 249c, respectively. Each of the gas supply holes 250a to 250c is opened to oppose (face) the exhaust port 231a in a plane view, and enables a gas to be supplied toward the wafers 200.

From the gas supply pipe 232a illustrated in FIG. 1, a modifying agent is supplied into the process chamber 201 via the MFC 241a, the valve 243a, and the nozzle 249a. From the gas supply pipe 232b, a first precursor is supplied to the process chamber 201 via the MFC 241b, the valve 243b, and the nozzle 249b. The first precursor is used as one of a first film-forming agent. From the gas supply pipe 232e, a second precursor is supplied into the process chamber 201 via the MFC 241e, the valve 243e, and the nozzle 249b. The second precursor is used as one of a second film-forming agent. From the gas supply pipe 232c, a reactant is supplied into the process chamber 201 via the MFC 241c, the valve 243c, and the nozzle 249c. The reactant is used as one of a film-forming agent. From the gas supply pipe 232d, a catalyst is supplied into the process chamber 201 via the MFC 241d, the valve 243d, the gas supply pipe 232a, and the nozzle 249a. The catalyst is used as one of the film-forming agent. From the gas supply pipes 232f to 232h, an inert gas is supplied into the process chamber 201 via the MFCs 241f to 241h, the valves 243f to 243h, the gas supply pipes 232a to 232c, and the nozzles 249a to 249c, respectively. The inert gas acts as a purge gas, a carrier gas, a dilution gas, or the like. In addition, from the gas supply pipe 272, a removing agent is supplied into the process chamber 201 via the MFC 271, the valve 273, and the nozzle 249a.

Mainly, a modifying agent supply system includes the gas supply pipe 232a, the MFC 241a, and the valve 243a, a first precursor supply system includes the gas supply pipe 232b, the MFC 241b, and the valve 243b, a second precursor supply system includes the gas supply pipe 232e, the MFC 241e, and the valve 243e, a reactant supply system includes the gas supply pipe 232c, the MFC 241c, and the valve 243c, a catalyst supply system includes the gas supply pipe 232d, the MFC 241d, and the valve 243d, and an inert gas supply system includes the gas supply pipes 232f to 232h, the MFCs 241f to 241h, and the valves 243f to 243h. Each or the entirety of the first precursor supply system, the second precursor supply system, the reactant supply system, and the catalyst supply system is referred to as a film-forming agent supply system. Further, mainly, a removing agent supply system is composed of the gas supply pipe 272, the MFC 271, and the valve 273.

Any one or the whole of the above-described various supply systems may be configured as an integrated gas supply system 248 in which the valves 243a to 243h and 273, the MFCs 241a to 241h and 271, and the like are integrated.

The exhaust port 231a for exhausting an atmosphere in the process chamber 201 is provided in a lower portion of a sidewall of the reaction tube 203. An exhaust pipe 231 is connected to the exhaust port 231a. A vacuum pump 246 is connected to the exhaust pipe 231 via a pressure sensor 245 for detecting a pressure in the process chamber 201 and an APC (Auto Pressure Controller) valve 244. The APC valve 244 is configured to perform or stop vacuum exhaust in the process chamber 201 by opening/closing the valve in a state in which the vacuum pump 246 is actuated, and is also configured to regulate the pressure in the process chamber 201 by adjusting an opening degree of the valve, based on pressure information detected by the pressure sensor 245. Mainly, an exhaust system includes the exhaust pipe 231, the APC valve 244, and the pressure sensor 245. The vacuum pump 246 may be included in the exhaust system.

A seal cap 219 configured to be capable of airtightly sealing a lower end opening of the manifold 209 via an O-ring 220b is provided below the manifold 209. Below the seal cap 219, a rotator 267 configured to rotate a boat 217 is installed. A rotary shaft 255 of the rotator 267 is connected to the boat 217. The rotator 267 is configured to rotate the wafers 200 by rotating the boat 217. A boat elevator 115 is configured as a transferer which loads and unloads the wafers 200 into and out of the process chamber 201 by moving the seal cap 219 up and down.

Below the manifold 209, a shutter 219s configured to be capable of airtightly sealing the lower end opening of the manifold 209 via an O-ring 220c in a state in which the boat 217 is unloaded from the process chamber 201 by lowering the seal cap 219 is installed.

The boat 217 as a substrate support is configured to support a plurality of wafers 200, e.g., 25 to 200 wafers 200, in a horizontal posture and in multiple stages while vertically arranging the wafers 200 with the centers thereof aligned with each other, i.e., to arrange the wafers 200 at intervals. Heat insulating plates 218 made of a heat-resistant material are supported in multiple stages at a bottom of the boat 217.

Inside the reaction tube 203, a temperature sensor 263 is installed. By regulating a state of supply of electric power to the heater 207, based on temperature information detected by the temperature sensor 263, a temperature inside the process chamber 201 becomes a desired temperature distribution.

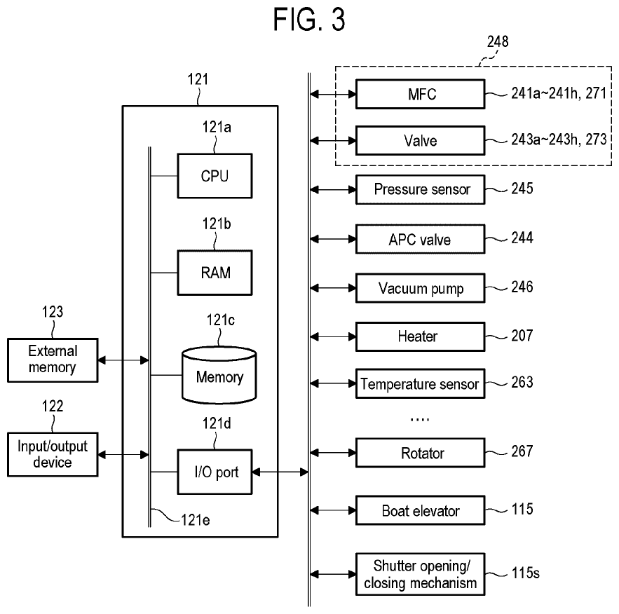

As illustrated in FIG. 3, the controller 121, which is a control part, is configured as a computer including a CPU (Central Processing Unit) 121a, a RAM (Random Access Memory) 121b, a memory 121c, and an I/O port 121d. The RAM 121b, the memory 121c, and the I/O port 121d are configured to exchange data with the CPU 121a via an internal bus 121e. An input/output device 122 configured as, for example, a touch panel or the like is connected to the controller 121. Further, the controller is configured to be capable of being connected to an external memory 123. The memory 121c includes, for example, a flash memory, an HDD (Hard Disk Drive), an SSD (Solid State Drive), or the like. In the memory 121c, a control program for controlling an operation of the substrate processing apparatus, a process recipe in which procedures and conditions of a substrate processing to be described later are written, and the like are readably recorded and stored. The process recipe is a combination which causes the controller 121 to execute the respective procedures in a substrate processing which is described later in the substrate processing apparatus so as to obtain a predetermined result. The process recipe functions as a program. Hereinafter, the process recipe, the control program and the like are collectively and simply referred to as a program. Furthermore, the process recipe is also simply referred to as a recipe. The RAM 121b is configured as a memory area (work area) in which programs, data, and the like, which are read by the CPU 121a, are temporarily held.

The I/O port 121d is connected to the MFCs 241a to 241h and 271, the valves 243a to 243h and 273, the pressure sensor 245, the APC valve 244, the vacuum pump 246, the temperature sensor 263, the heater 207, the rotator 267, the boat elevator 115, and the like.

The CPU 121a is configured to be capable of reading and executing the control program from the memory 121c and reading the recipe from the memory 121c in response to an input of an operation command from the input/output device 122, or the like. The CPU 121a is configured to be capable of, according to contents of the read recipe, controlling the flow rate regulating operations for various materials (various gases) by the MFCs 241a to 241h and 271, opening/closing operations of the valves 243a to 243h and 273, an opening/closing operation of the APC valve 244, the pressure regulating operation by the APC valve 244 based on the pressure sensor 245, the start and stop of the vacuum pump 246, the temperature regulating operation of the heater 207 based on the temperature sensor 263, the rotation and rotational speed adjusting operation of the boat 217 by the rotator 267, the operation of moving the boat 217 up and down by the boat elevator 115, and the like.

The controller 121 may be configured by installing, on the computer, the above-described program recorded and stored in the external memory 123. The external memory 123 includes, for example, a magnetic disk such as an HDD, an optical disk such as a CD, a magneto-optical disk such as an MO, a semiconductor memory such as a USB memory or an SSD, and the like. The memory 121c or the external memory 123 is configured as a computer-readable recording medium. Hereinafter, the memory 121c and the external memory 123 are collectively and simply referred to as a recording medium. In addition, provision of the program to the computer may be performed by using a communication means such as the Internet or a dedicated line instead of using the external memory 123.

### (2) Substrate Processing Process

Next, a substrate processing process is described.

First, a structure of a wafer 200 is described.

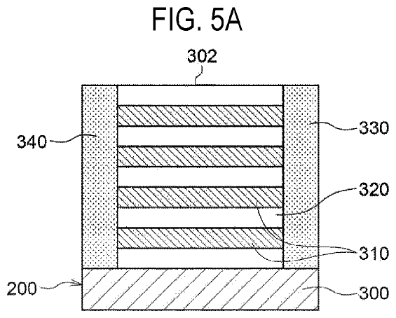

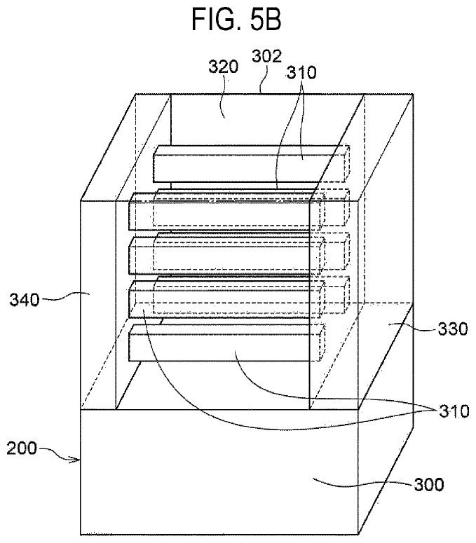

In FIG. 5A, an oblique line indicating a cross-section of a second film 320 is omitted so as to avoid obscurity due to complication of the drawing. Further, in FIG. 5B, portions of first film 310, which are hidden by the second film 320, are indicated by a solid line instead of an alternated long and short dash line so as to avoid obscurity due to complication of the drawing. Further, even in subsequent cross-sectional views, the oblique line indicating the cross-section of the second film 320 is omitted.

As illustrated in FIGS. 5A and 5B, the wafer 200 schematically includes, on a base material 300, the first film 310 formed in a rod shape and the second film 320 covering the first film 310.

In addition, for convenience, a vertical direction of the wafer 200 is described at a state in which the wafer 200 is loaded in the process furnace 202 of the substrate processing apparatus 10 (see FIG. 1). In addition, for convenience, a lateral direction of FIG. 5A is referred to as a length direction of the first film 310, and a direction orthogonal to the paper of FIG. 5A is referred to as a front-rear direction. A case viewed from a direction orthogonal to an upper surface of the base material 300 is referred as a case viewed on a plane.

In the embodiments, in a plane view, the first films 310 are formed to be arranged at a plurality of intervals in the front-rear direction. Further, in the embodiments, the first films 310 are composed of a plurality of films formed in a block shape (more specifically, a rod shape), which are arranged at intervals in the vertical direction orthogonal to the upper surface of the base material 300. From another viewpoint, the first films 310 are composed of films formed in a block shape, of which at least some are formed to be embedded in the second film 320 and which are arranged at intervals in the vertical direction and the front-rear direction.

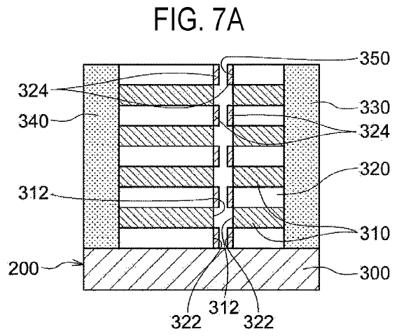

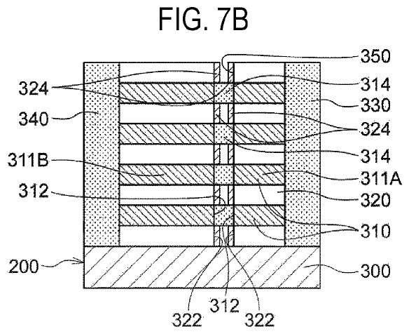

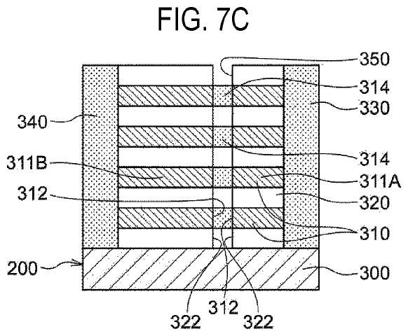

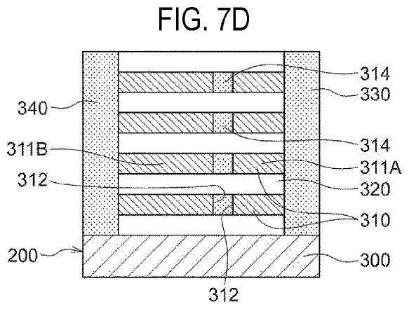

In addition, for convenience, a portion composed of the first films 310 and the second film 320 is referred to as a main portion 302. Side surfaces of the main portion 302 in the lateral direction are surfaces to which side surfaces of the first films 310 and the second film 320 are exposed. Specifically, a right side surface of the main portion 302 in the drawing is a side surface to which an end surface of a first portion 311A (see FIG. 7D) to be described later in the first film 310 and an end surface of the second film 320 are exposed. A left side surface of the main portion 302 in the drawing is a side surface to which an end surface of a second portion 311B (see FIG. 7D) to be described later in the first film 310 and an end surface of the second film 320 are exposed.

In the embodiments, on the base material 300 of the wafer 200, a third film 330 is formed adjacent to one side in the length direction of the first films 310 in the main portion 302, in other words, the right side surface in the lateral direction, to cover the first films 310. Further, on the base material 300 of the wafer 200, a fourth film 340 is formed adjacent to the other side in the length direction of the first films 310 in the main portion 302, in other words, the left side surface in the lateral direction, to cover the first films 310.

In this aspect, a surface film which is not illustrated is formed on a surface of the first film 310, which is in contact with the second film 320.

Hereinafter, for convenience, the first film 310 is described as a silicon film (Si film) serving as a non-oxidizing film (oxygen-free film), the surface film of the first film 310 is described as a SiO film serving as a gate insulating film, and the second film 320 is described as a silicon oxycarbide film (SiOC film) serving as an oxide film (oxygen containing film) or a carbide film (carbon containing film). Further, both the third film 330 and the fourth film 340 are described as silicon oxide films (SiO films). The base material 300 is preferably made of a material which is not etched in pre- and post-processes to be described later or of a material with a low etching rate with respect to a film to be etched. However, these are representative examples, and the present disclosure is not limited thereto.

In an example of the substrate processing process in the embodiments of the present disclosure, as a process of manufacturing a semiconductor device, a process of removing the first portion 311A while leaving the second portion 311B which is a portion of the first film 310 is performed by performing:
(a) providing the wafer 200 including the above-described structure in which the first films 310 and the second film 320 covering the first films 310 are formed, replacing a part of a portion of the first film 310, which is covered by the second film 320, with a stopper 314 (see FIG. 7D), and dividing the first film 310 into the first portion 311A and the second portion 311B (see FIG. 7D), by the stopper 314; and
(b) leaving the second portion 311B by removing the first portion 311A which extends from an end surface, not covered by the second film 320, to the stopper 314.

Hereinafter, an example of the substrate processing process, in which the stopper 314 is formed in the first film 310 formed on the base material 300 of the wafer 200 serving as a substrate illustrated in FIG. 5B, by using the substrate processing apparatus 10, and the first film 310 is divided into the first portion 311A and the second portion 311B, is described. In addition, the “stopper” is also referred to as a “stopper film.”

Further, in the example of the substrate processing process in the embodiments of the present disclosure, a process not using the substrate processing apparatus 10 is also included. Specifically, the process includes a “pre-process” before the stopper 314 (see FIG. 7D) is formed in the first film 310 of the wafer 200, which is described later, and a “post-process” after the stopper 314 is formed, which is described later. In the “pre-process” and the “post-process,” the substrate processing apparatus 10 is not used.

Further, the example of the substrate processing process, is also an example of a method of processing a substrate or a method of manufacturing a semiconductor device. In addition, in the following description, an operation of each part constituting the substrate processing apparatus 10 is controlled by the controller 121.

First, the pre-process in the example of the substrate processing process is described in detail.

### Pre-Process

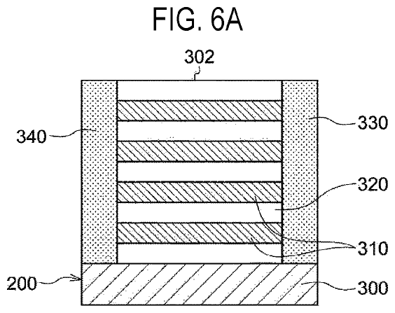

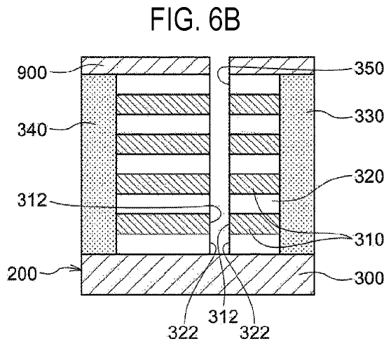

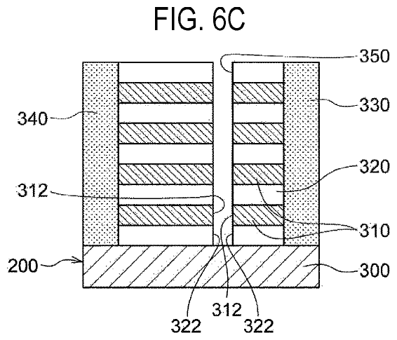

In the pre-process, with respect to the wafer 200 illustrated in FIG. 6A, a groove 350 along the front-rear direction is formed in the main portion 302 of the wafer 200 in a plane view as illustrated in FIG. 6B.

Specifically, as illustrated in FIG. 6B, a hard mask 900 is formed on an upper surface of the wafer 200, which is opposite to the base material 300, and the groove 350 penetrating through the first films 310 and the second film 320 is formed through etching. More specifically, the groove 350 is formed to penetrate through the second film 320 and some of portions of the first films 310, which are covered by the second film 320. In addition, for convenience, end surfaces of the first film 310, which are exposed in the groove 350, are referred to as first end surfaces 312. Similarly, for convenience, end surfaces of the second film 320, which are exposed in the groove 350, are referred to as second end surfaces 322.

As the etching, for example, anisotropic etching by a carbon fluoride (CF)-based gas plasma may be used. Further, in the case of the anisotropic etching, a plasma-excited gas is preferably used. As the CF-based gas, for example, one or more of CF₄, C₄F₆, C₄F₈, CH₂F₂, CHF₃, and the like may be used. An etching processing in this process may be performed using a well-known etching apparatus capable of performing an etching processing on the wafer 200. The same applies to other etching processings in subsequent processes. Further, in the etching processing in this process, a plasma etching apparatus which enables etching with anisotropy in the vertical direction, such as penetrating through the first films 310 and the second film 320, is preferably used.

In addition, as illustrated in FIG. 6C, after the groove 350 is formed, the hard mask 900 is removed. A removal processing of a hard mask in this process may be performed using, for example, a well-known ashing apparatus capable of performing an ashing processing on a hard mask on the wafer 200. The same applies to other removal processings of hard masks in subsequent processes.

Next, a process of forming the stopper 314 is described in detail. Further, in the following description, as a part of the process of forming the stopper, an example of performing a removal step of removing a modified layer 324 to be described later and a second film formation step of re-filling the groove 350 with the second film 320 is described, but the process of forming the stopper may not include these steps.

### Process of Forming Stopper

In the following example, a case where a film-forming agent includes a precursor, a reactant, and a catalyst is described. The precursor, the reactant, and the catalyst contain different molecular structures. Further, in the following example, a case where a described above specific material included in the film-forming agent is the precursor is described. That is, a case where molecule X is a precursor molecule is described. Further, the above-described specific material included in the film-forming agent may be the reactant. That is, the molecule X may be a reactant molecule. Further, the above-described specific material included in the film-forming agent may be the catalyst. That is, the molecule X may be a catalyst molecule. That is, the above-described specific material included in the film-forming agent may include at least one selected from the group of the precursor, the reactant, and the catalyst.

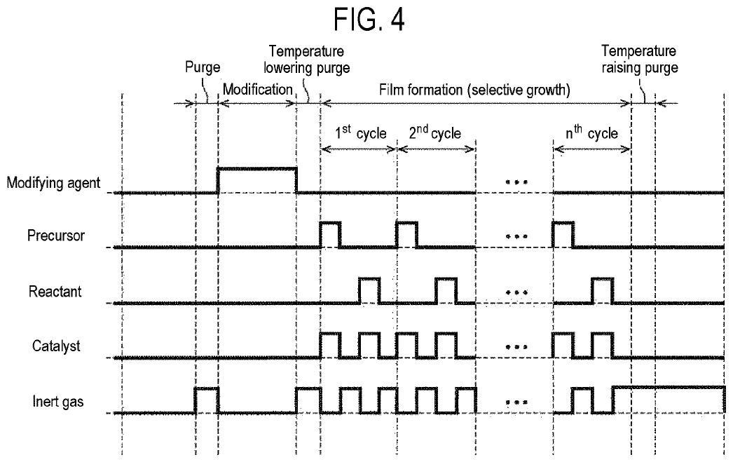

In addition, in the following example, as illustrated in FIG. 4, a case where a cycle including a step of supplying the first precursor to the wafer 200 and a step of supplying the reactant to the wafer 200 is performed a predetermined number of times in a first film formation step, and the catalyst is supplied to the wafer 200 in at least one selected from the group of the step of supplying the first precursor and the step of supplying the reactant is described. Further, in FIG. 4, an example in which the catalyst is supplied in both the step of supplying the first precursor and the step of supplying the reactant is described as a representative example.

That is, a processing sequence illustrated in FIG. 4 represents an example of, under an atmosphere of non-plasma, performing:
a modification step of forming the modified layer 324 by supplying the modifying agent to the wafer 200 to deposit at least a portion of a molecular structure of molecules constituting the modifying agent on the second end surface 322 of the second film 320, which is described later; and
a first film formation step of forming the stopper 314 on the first end surface 312 of the first film 310 by performing, a predetermined number of times (n times) (n is an integer of 1 or more, the same below), a cycle including a step of supplying the first precursor and the catalyst to the wafer 200 and a step of supplying the reactant and the catalyst to the wafer 200.

From another viewpoint, the first film formation step is a step of replacing a portion of the first film 310 with the stopper 314, and dividing the first film 310 into the first portion 311A and the second portion 311B by using the stopper 314.

In the present disclosure, for convenience, the above-described processing sequence may be represented as follows. In description of other embodiments to be described later, the same representation may be used.

$$Modifying agent \to ( first precursor + catalyst \to reactant + catalyst ) \times n$$

Further, like a processing sequence illustrated below, the catalyst may be supplied to the wafer 200 in at least one selected from the group of the step of supplying the first precursor and the step of supplying the reactant.

$$Modifying agent \to ( first precursor + catalyst \to reactant ) \times n$$

$$Modifying agent \to ( first precursor \to reactant + catalyst ) \times n$$

$$Modifying agent \to ( first precursor + catalyst \to reactant + catalyst ) \times n$$

In addition, the term “wafer” used in the present disclosure may mean a wafer itself or a stacked body including the wafer and a predetermined layer or film formed on a surface thereof. The term “surface of a wafer” used in the present disclosure may mean a surface of the wafer itself or a surface of a predetermined layer or the like, which is formed on the wafer. The term “forming a predetermined layer on a wafer” used in the present disclosure may mean forming the predetermined layer directly on a surface of the wafer itself or forming the predetermined layer on a layer or the like, which is formed on the wafer. A case where the term “substrate” is used in the present disclosure is also the same as the case where the term “wafer” is used.

Further, the term “agent” used in the present disclosure includes at least one selected from the group of a gas phase material and a liquid phase material. The liquid material includes a mist-like material.

The term “layer” used in the present disclosure includes at least one selected from the group of a continuous layer and a discontinuous layer. For example, if an inhibitor layer enables a film formation inhibiting action to occur, the inhibitor layer may include a continuous layer, may include a discontinuous layer, or may include both the continuous layer and the discontinuous layer.

### Wafer Charging and Boat Loading

First, when a plurality of wafers 200, in which the groove 350 illustrated in FIG. 6C is formed, is loaded on the boat 217 of the substrate processing apparatus 10 illustrated in FIG. 1, the lower end opening of the manifold 209 is opened by a shutter opening/closing mechanism 115s. Afterwards, as illustrated in FIG. 1, the boat 217 supporting the plurality of wafers 200 is lifted by the boat elevator 115 to be loaded (boat-loaded) into the process chamber 201. In this state, the seal cap 219 is in a state where the seal cap 219 seals a lower end of the manifold 209.

### Pressure Regulating and Temperature Regulating

After the boat loading is completed, an interior of the process chamber 201, i.e., a space in which the wafers 200 exist, is vacuum-exhausted (decompression-exhausted) by the vacuum pump 246 to reach a desired pressure (degree of vacuum). At this time, the pressure in the process chamber 201 is measured by the pressure sensor 245, and the APC valve 244 is feedback-controlled based on the measured pressure information. Further, the wafers 200 in the process chamber 201 are heated by the heater 207 to reach a desired processing temperature. At this time, the state of supply of electric power to the heater 207 is feedback-controlled based on the temperature information detected by the temperature sensor 263 such that the interior of the process chamber 201 becomes a desired temperature distribution. Further, rotation of the wafers 200 by the rotator 267 is initiated. The exhaust in the process chamber 201 and the heating and rotation of the wafers 200 are continuously performed at least until the processing on the wafers 200 is completed.

### Modification Step

Next, as illustrated in FIG. 7A, the modified layer 324 is formed on the second end surfaces 322 of the second film 320, which is a SiOC film exposed in the groove 350, by supplying the modifying agent to the wafer 200. That is, by supplying the modifying agent reacting with the second end surfaces 322 exposed in the groove 350 of the wafer 200, the modified layer 324 is selectively formed on the second end surfaces 322.

Specifically, by opening the valve 243a of the substrate processing apparatus 10 illustrated in FIG. 1, the modifying agent flows into the gas supply pipe 232a. A flow rate of the modifying agent is regulated by the MFC 241a, and the modifying agent is supplied into the process chamber 201 via the nozzle 249a and exhausted from the exhaust port 231a. At this time, the modifying agent is supplied to the wafer 200 from a side direction of the wafers 200 (modifying agent supply). At this time, by opening the valves 243f to 243h, the inert gas may be supplied into the process chamber 201 respectively via the nozzles 249a to 249c.

In the embodiments, the modified layer 324 illustrated in FIG. 7A is an inhibitor layer. Specifically, by supplying the modifying agent to the wafers 200 under processing conditions which are described later, inhibitor molecules which are at least a portion of the molecular structure of the molecules constituting the modifying agent is chemically adsorbed on the second end surfaces 322 exposed in the groove 350, and the second end surfaces 322 may be modified such that the modified layer 324, which is the inhibitor layer, is formed on the second end surfaces 322. That is, in this step, by supplying the modifying agent reacting with the second end surfaces 322 to the wafers 200, the second end surfaces 322 may be modified such that the inhibitor molecules included in the modifying agent are adsorbed on the second end surfaces 322 and the modified layer 324 is formed. Further, the inhibitor molecules are also referred to as film formation inhibiting molecules (adsorption inhibiting molecules, reaction inhibiting molecules). Further, the modified layer 324 is also referred to as a film formation inhibiting layer (adsorption inhibiting layer, reaction inhibiting layer).

The modified layer 324 formed in this step includes at least a portion of the molecular structure of the molecules constituting the modifying agent, which is a residue derived from the modifying agent. In a first film formation step which is described later, the modified layer 324 prevents adsorption of at least a portion of a molecular structure of molecules constituting the first precursor (film-forming agent) on the second end surfaces 322, thereby inhibiting (suppressing) progress of a film forming reaction on the second end surfaces 322.

As the at least a portion of the molecular structure of the molecules constituting the modifying agent, i.e., the inhibitor molecules, for example, a trialkylsilyl group such as a trimethylsilyl group (—SiMe₃) or triethylsilyl group (—SiEt₃) is exemplified. The trialkylsilyl group includes an alkyl group, i.e., a hydrocarbon group. In this case, Si of the trimethylsilyl group or the triethylsilyl group is adsorbed on an adsorption site in the second end surface 322 of the wafer 200. In a case where the second end surface 322 is a surface of the SiOC film, the second end surface 322 includes an OH termination (OH group) as the adsorption site, and the Si of the trimethylsilyl group or the triethylsilyl group is bonded to O of the OH termination (OH group) in the second end surface 322. The second end surface 322 is terminated by an alkyl group, such as a methyl group or an ethyl group, i.e., a hydrocarbon group. The alkyl group (alkylsilyl group), such as the methyl group (trimethylsilyl group) or the ethyl group (triethylsilyl group), i.e., the hydrocarbon group constitutes the inhibitor layer, and, in a first film formation step which is described later, prevents adsorption of at least a portion of the molecular structure of molecules constituting the first precursor (film-forming agent) on the second end surfaces 322, thereby inhibiting (suppressing) progress of a film formation reaction on the second end surfaces 322.

In addition, in this step, at least a portion of the molecular structure of the molecules constituting the modifying agent is also adsorbed on a portion of the first end surface 312 of the first film 310 which is the Si film of the wafer 200, but an adsorption amount thereof is slight, and hence an adsorption amount on the second end surface 322 of the wafer 200 becomes overwhelmingly large. The reason why such selective (preferential) adsorption is possible is that processing conditions in this step are set as conditions in which the modifying agent is not vapor-phase decomposed in the process chamber 201. Further, the selective (preferential) adsorption is possible because the second end surface 322 is OH-terminated throughout an entire region thereof, whereas most regions of the first end surface 312 are not OH-terminated. In this step, since the modifying agent is not vapor-phase decomposed in the process chamber 201 (see FIG. 1), at least a portion of the molecular structure of the molecules constituting the modifying agent is not deposited multiple times on the first end surface 312 and the second end surface 322, and is selectively adsorbed on the second end surface 322 among the first and second end surfaces 312 and 322. Accordingly, the second end surface 322 is selectively terminated by the at least a portion of the molecular structure of the molecules constituting the modifying agent.

Processing conditions when supplying the modifying agent in the modification step are exemplified as follows.
Processing temperature: room temperature (25 degrees C.) to 500 degrees C., specifically room temperature to 250 degrees C.
Processing pressure: 5 Pa to 2000 Pa, specifically 10 Pa to 1000 Pa
Processing time: 1 sec to 120 min, specifically 30 sec to 60 min
Modifying agent supply flow rate: 0.001 slm to 3 slm, specifically 0.001 slm to 0.5 slm
Inert gas supply flow rate (for each gas supply pipe): 0 slm to 20 slm

In addition, expression of a numerical value range such as “5 Pa to 2000 Pa” in the present disclosure means that a lower limit and an upper limit are included in the range. Therefore, for example, “5 Pa to 2000 Pa” means “5 Pa or more and 2000 Pa or less.” Other numerical value ranges are the same as above.

In addition, in a case where 0 slm is included in a supply flow rate of a material (gas), 0 slm means a case where the material (gas) is not supplied. This is the same in the following description.

In addition, a processing temperature in the present disclosure means a temperature of the wafer 200 or the temperature in the process chamber 201, and a processing pressure in the present disclosure means the pressure in the process chamber 201. Further, a processing time in the present disclosure means a time for which a processing is continued. These are the same in the following description.

After the modified layer 324 is selectively formed on the second end surfaces 322 of the second film 320 of the wafer 200, the valve 243a illustrated in FIG. 1 is closed, to stop the supply of the modifying agent into the process chamber 201. A gas phase material or the like, which remains in the process chamber 201, is excluded (purged) from the interior of the process chamber 201. In addition, a processing temperature when purge is performed in this step is preferably set as a temperature similar to the processing temperature when the modifying agent is supplied.

As the modifying agent, for example, a compound with a structure in which an amino group is directly bonded to silicon (Si) or a compound with a structure in which an amino group and an alkyl group are directly bonded to silicon (Si) may be used.

As the modifying agent, for example, (dimethylamino)trimethylsilane ((CH₃)₂NSi(CH₃)₃), (diethylamino)triethylsilane ((C₂H₅)₂NSi(C₂H₅)₃), (dimethylamino)triethylsilane ((CH₃)₂NSi(C₂H₅)₃), (diethylamino)trimethylsilane ((C₂H₅)₂NSi(CH₃)₃), (dipropylamino)trimethylsilane ((C₃H₇)₂NSi(CH₃)₃), (dibutylamino)trimethylsilane ((C₄H₉)₂NSi(CH₃)₃), (trimethylsilyl)amine ((CH₃)₃SiNH₂), (triethylsilyl)amine ((C₂H₅)₃SiNH₂), (dimethylamino)silane ((CH₃)₂NSiH₃), (diethylamino)silane ((C₂H₅)₂NSiH₃), (dipropylamino)silane ((C₃H₇)₂NSiH₃), (dibutylamino)silane ((C₄H₉)₂NSiH₃), and the like may be used. As the modifying agent, one or more of these may be used.

Further, as the modifying agent, for example, bis(dimethylamino)dimethylsilane ([(CH₃)₂N]₂Si(CH₃)₂), bis(diethylamino)diethylsilane ([(C₂H₅)₂N]₂Si(C₂H₅)₂), bis(dimethylamino)diethylsilane ([(CH₃)₂N]₂Si(C₂H₅)₂), bis(diethylamino)dimethylsilane ([(C₂H₅)₂N]₂Si(CH₃)₂), bis(dimethylamino)silane ([(CH₃)₂N]₂SiH₂), bis(diethylamino)silane ([(C₂H₅)₂N]₂SiH₂), bis(dimethylaminodimethylsilyl)ethane ([(CH₃)₂N(CH₃)₂Si]₂C₂H₆), bis(dipropylamino)silane ([(C₃H₇)₂N]₂SiH₂), bis(dibutylamino)silane ([(C₄H₉)₂N]₂SiH₂), bis(dipropylamino)dimethylsilane ([(C₃H₇)₂N]₂Si(CH₃)₂), bis(dipropylamino)diethylsilane ([(C₃H₇)₂N]₂Si(C₂H₅)₂), (dimethylsilyl)diamine ((CH₃)₂Si(NH₂)₂), (diethylsilyl)diamine ((C₂H₅)₂Si(NH₂)₂), (dipropylsilyl)diamine ((C₃H₇)₂Si(NH₂)₂), bis(dimethylaminodimethylsilyl)methane ([(CH₃)₂N(CH₃)₂Si]₂CH₂), bis(dimethylamino)tetramethyldisilane ([(CH₃)₂N]₂(CH₃)₄Si₂), and the like may be used. As the modifying agent, one or more of these may be used.

### First Film Formation Step

After the modification step is performed, as illustrated in FIG. 7B, by supplying the first film-forming agent into the groove 350 of the wafer 200, the stopper 314 is formed on the first end surfaces 312 of the first film 310, which is the Si film exposed in the groove 350 of the wafer 200. Specifically, by supplying the first precursor reacting with the first end surfaces 312 into the groove 350 of the wafer 200, at least a portion of the molecular structure of the molecules constituting the first precursor is selectively adsorbed on the first end surfaces 312. Next, by reacting an adsorbed layer formed by the adsorption with the reactant, at least a portion of the stopper 314 is formed (i.e., deposited). More specifically, the stopper 314 is deposited, i.e., grown from each of both the first end surfaces 312 exposed in the groove 350, to be embedded between the first end surfaces 312.

A portion of the first film 310 at one side of the stopper 314 is referred to as a first portion 311A, and a portion of the first film 310 at the other side of the stopper 314 is referred to as a second portion 311B. From another viewpoint, the stopper 314 is formed to be embedded between the first end surfaces 312 of the first film 310, so that a portion of the first film 310 is replaced with the stopper 314. Accordingly, the stopper 314 divides the first film 310 into the first portion 311A and the second portion 311B.

Compositions of the stopper 314 and the second film 320 are different from each other. Specifically, in the embodiments, the stopper 314 is a silicon oxide film (SiO film). That is, the first film formation step is, for example, selective formation of the SiO film, using a halogen-containing Si precursor.

Specifically, a next precursor supply step and a reactant supply step are sequentially performed. Further, in the following example, as described above, the first film-forming agent includes the first precursor, the reactant, and the catalyst. In the precursor supply step and the reactant supply step, an output of the heater 207 is regulated, thereby maintaining a state in which the temperature of the wafer 200 is at a temperature equal to or lower than the temperature of the wafer 200 in the modification step. In particular, by maintaining a temperature substantially equal to the temperature of the wafer 200 in the modification step, a time needed for changing the temperature of the wafer 200 is omitted, thus reducing the processing time. Further, by maintaining a state in which the temperature of the wafer 200 is lower than temperature of the wafer 200 in the modification step, it is possible to more effectively suppress at least a portion of the modified layer 324 from being desorbed.

### Precursor Supply Step

In this step, with respect to the wafer 200 after the modification step is performed, i.e., the wafer 200 after the modified layer 324 is selectively formed on the second end surfaces 322 of the second film 320, a first layer is formed on the first end surfaces 312 exposed in the groove 350 by supplying the first precursor (first precursor gas) and the catalyst (catalyst gas) as the first film-forming agent into the groove 350.

Further, the first layer formed in this step is in a state before being oxidized in the reactant supply step which is described later.

In this step, by opening the valves 243b and 243d of the substrate processing apparatus 10 illustrated in FIG. 1, the first precursor and the catalyst as the first film-forming agent flow into the gas supply pipes 232b and 232d, respectively. Flow rates of the first precursor and the catalyst are regulated by the MFCs 241b and 241d such that the first precursor and the catalyst are supplied into the process chamber 201 via the nozzles 249b and 249a, respectively. The first precursor and the catalyst are mixed in the process chamber 201 and exhausted from the exhaust port 231a. At this time, from the side direction of the wafer 200, the first precursor and the catalyst are supplied to the wafer 200 (supply of first precursor +catalyst). At this time, by opening the valves 243f to 243h, the inert gas may be supplied into the process chamber 201 respectively via the nozzles 249a to 249c.

By supplying the first precursor and the catalyst to the wafer 200 under processing conditions which are described later, it is possible to selectively chemically adsorb at least a portion of the molecular structure of the molecules constituting the first precursor on the first end surfaces 312 while suppressing chemical adsorption of at least a portion of the molecular structure of the molecules constituting the first precursor on the second film 320. Accordingly, the first layer is formed on the first end surfaces 312 of the wafer 200. Further, the first layer includes at least a portion of the molecular structure of molecules constituting the first precursor, which is a residue of the first precursor. That is, the first layer includes at least a portion of atoms constituting the first precursor.

In this step, by supplying the catalyst together with the first precursor, the above-described reaction may progress under an atmosphere of non-plasma and under a low temperature condition to be described later. As such, the formation of the first layer is performed under the atmosphere of non-plasma and under the low temperature condition to be described later, so that it is possible for molecules or atoms constituting the modified layer 324 formed on the second end surfaces 322 to be maintained without being removed (desorbed) from the second end surfaces 322.

Further, by performing the formation of the first layer under the atmosphere of non-plasma and under the low temperature condition to be described later, the first precursor may not be thermally decomposed (vapor-phase decomposed), i.e., self-decomposed in the process chamber 201. Accordingly, it is possible to suppress the at least a portion of the molecular structure of the molecules constituting the first precursor from being deposited multiple times on the first end surfaces 312 and the second end surfaces 322, and to selectively adsorb the at least a portion of the molecular structure of the molecules constituting the first precursor on the first end surfaces 312.

In addition, in this step, at least a portion of the molecular structure of the molecules constituting the first precursor is also adsorbed on a portion of the second end surface 322, but an adsorption amount thereof is slight, and hence an adsorption amount on the first end surface 312 of the wafer 200 becomes overwhelmingly large. The reason why such selective adsorption is possible is that processing conditions in this step are in the low temperature condition to be described later and are set as conditions in which the first precursor is not vapor-phase decomposed in the process chamber 201. Further, the selective adsorption is possible because while the modified layer 324 is formed on the second end surface 322, the modified layer 324 is not formed in most regions of the first end surface 312.

Processing conditions when supplying the first precursor and the catalyst in the precursor supply step are exemplified as follows.
Processing temperature: room temperature (25 degrees C.) to 200 degrees C., specifically room temperature to 150 degrees C.
Processing pressure: 133 Pa to 1333 Pa
First precursor supply flow rate: 0.001 slm to 2 slm
Catalyst supply flow rate: 0.001 slm to 2 slm
Inert gas supply flow rate (for each gas supply pipe): 0 slm to 20 slm
Each gas supply time: 1 sec to 120 sec, specifically 1 sec to 60 sec

After the first layer is selectively formed in the wafer 200, the valves 243b and 243d are closed, and the supply of each of the first precursor and the catalyst into the process chamber 201 is stopped. In addition, by a processing sequence and processing conditions similar to the purge in the modification step, a gas phase material or the like, which remains in the process chamber 201, is excluded (purged) from the interior of the process chamber 201. In addition, a processing temperature when purge is performed in this step is preferably set as a temperature similar to the processing temperature when the first precursor and the catalyst are supplied.

As the first precursor, for example, a Si- and halogen-containing gas may be used. Halogen includes chlorine (Cl), fluorine (F), bromine (Br), iodine (I), and the like. The Si- and halogen-containing gas preferably contains the halogen in a form of a chemical bond between Si and halogen. As the Si- and halogen-containing gas, for example, a chlorosilane-based gas may be used. The Si- and halogen-containing gas may further include O, and preferably includes the O, for example, in a form of a siloxane bond (Si—O—Si bond). As the Si- and halogen-containing gas, for example, a chlorosiloxane-based gas may be used. These gases preferably include Cl in a form of a Si—Cl bond. As the first precursor, apart from these gases, an amino group-containing gas such as an aminosilane-based gas may be used.

As the first precursor, for example, tetrachlorosilane (SiCl₄), hexachlorodisilane (Si₂Cl₆), octachlorotrisilane (Si₃Cl₈), and the like may be used. Further, as the first precursor, for example, hexachlorodisiloxane (Cl₃Si—O—SiCl₃), octachlorotrisiloxane (Cl₃Si—O—SiCL₂—O—SiCl₃), and the like may be used. As the first precursor, one or more of these may be used.

Further, as the first precursor, for example, tetrakis(dimethylamino)silane (Si[N(CH₃)₂]₄), tris(dimethylamino)silane (Si[N(CH₃)₂]₃H), bis(diethylamino)silane (Si[N(C₂H₅)₂]₂H₂), bis(tert-butylamino)silane (SiH₂[NH(C₄H₉)]₂), (diisopropylamino)silane (SiH₃[N(C₃H₇)₂], and the like may be used. As the first precursor, one or more of these may be used.

As the catalyst, for example, an amine-based gas containing carbon (C), nitrogen (N), and hydrogen (H) may be used. As the amine-based gas, a cyclic amine-based gas or a chain amine-based gas may be used. As the catalyst, for example, cyclic amines such as pyridine (C₅H₅N), aminopyridine (C₅H₆N₂), picoline (C₆H₇N), lutidine (C₇H₉N), pyrimidine (C₄H₄N₂), quinoline (C₉H₇N), piperazine (C₄H₁₀N₂), piperidine (C₅H₁₁N), and aniline (C₆H₇N) may be used. Further, as the catalyst, for example, chain amines such as triethylamine ((C₂H₅)₃N), diethylamine ((C₂H₅)₂NH), monoethylamine ((C₂H₅)NH₂), trimethylamine ((CH₃)₃N), dimethylamine ((CH₃)₂NH), and monomethylamine ((CH₃)NH₂) may be used. As the catalyst, one or more of these may be used. This is the same in a reactant supply step to be described later.

### Reactant Supply Step

After the precursor supply step is completed, the reactant (reaction gas) and the catalyst (catalyst gas) as the first film-forming agent are supplied to the wafer 200, i.e., the wafer after the first layer is selectively formed. Herein, an example in which an oxidizing agent (oxidizing gas) is used as the reactant (reaction gas) is described.

Specifically, by opening the valves 243c and 243d, the reactant and the catalyst flow into the gas supply pipes 232c and 232d, respectively. Flow rates of the reactant and the catalyst are regulated by the MFCs 241c and 241d such that the reactant and the catalyst are supplied into the process chamber 201 via the nozzles 249c and 249a, respectively. The reactant and the catalyst are mixed in the process chamber 201 and exhausted from the exhaust port 231a. At this time, from the side direction of the wafer 200, the reactant and the catalyst are supplied to the wafer 200 (supply of reactant+catalyst). At this time, by opening the valves 243f to 243h, the inert gas may be supplied into the process chamber 201 respectively via the nozzles 249a to 249c.

By supplying the reactant and the catalyst to the wafer 200 under processing conditions to be described later, at least a portion of the first layer formed in the precursor supply step is oxidized. Accordingly, as the first layer is oxidized, a second layer is formed.

In this step, by supplying the catalyst together with the reactant, the above-described reaction may progress under an atmosphere of non-plasma and under a low temperature condition to be described later. As such, oxidization of the stopper 314 is performed under the atmosphere of non-plasma and under the low temperature condition to be described later, so that it is possible for molecules or atoms constituting the modified layer 324 formed on the second end surfaces 322 to be maintained without being removed (desorbed) from the second end surfaces 322.

Processing conditions when supplying the reactant and the catalyst in the reactant supply step are exemplified as follows.
Processing temperature: room temperature (25 degrees C.) to 200 degrees C., specifically room temperature to 150 degrees C.
Processing pressure: 133 Pa to 1333 Pa
Reactant supply flow rate: 0.001 slm to 2 slm
Catalyst supply flow rate: 0.001 slm to 2 slm
Inert gas supply flow rate (for each gas supply pipe): 0 slm to 20 slm
Each gas supply time: 1 sec to 120 sec, specifically 1 sec to 60 sec

After the first layer is changed (converted) into the second layer by being oxidized, the valves 243c and 243d are closed, to stop the supply of each of the reactant and the catalyst into the process chamber 201. In addition, by a processing sequence and processing conditions similar to the purge in the above-described modification step, a gas phase material or the like, which remains in the process chamber 201, is excluded (purged) from the interior of the process chamber 201. In addition, a processing temperature when purge is performed in this step is preferably set as a temperature similar to the processing temperature when the reactant and the catalyst are supplied.

As the reactant, i.e., the oxidizing agent, for example, an oxygen (O)- and hydrogen (H)-containing gas may be used. As the O- and H-containing gas, for example, steam (H₂O gas), hydrogen peroxide (H₂O₂) gas, hydrogen (H₂) gas+oxygen (O₂) gas, H₂ gas+ozone (O₃) gas, and the like may be used. That is, as the O- and H-containing gas, O-containing gas+H-containing gas may be used. In this case, as the H-containing gas, deuterium (D₂) gas may be used instead of the H₂ gas. As the reactant, one or more of these may be used.

Further, the joint writing of two gases such as “H₂ gas+O₂ gas” means a mixed gas of a H₂ gas and an O₂ gas. When supplying a mixed gas, two gases may be mixed (premixed) in a supply pipe and then supplied into the process chamber 201, or two gases may be separately supplied to the process chamber 201 from different supply pipes and then mixed (post-mixed) within the process chamber 201.

Further, as the reactant, i.e., the oxidizing agent, an O-containing gas may be used in addition to the O- and H-containing gas. As the O-containing gas, for example, an O₂ gas, an O₃ gas, a nitrous oxide (N₂O) gas, a nitrogen monoxide (NO) gas, a nitrogen dioxide (NO₂) gas, a carbon monoxide (CO) gas, a carbon dioxide (CO₂) gas, and the like may be used. In addition to these, as the reactant, i.e., the oxidizing agent, the various solutions or the various cleaning liquids, which are described above, may be used. In this case, by exposing the wafer 200 to the cleaning liquid, an oxidization target material in the surface of the wafer 200 may be oxidized. As the reactant, one or more of these may be used.

As the catalyst, for example, catalysts like the various catalysts exemplified in the above-described precursor supply step may be used.

### Performing Predetermined Number of Times

By performing, a predetermined number of times (n times, where n is an integer of 1 or more), a cycle in which the above-described precursor supply step and the above-described reactant supply step are alternately performed non-simultaneously, i.e., without being synchronized with each other, a film as the stopper 314 may be selectively (preferentially) formed on the first end surfaces 312 of the first film 310 of the wafer 200 as illustrated in FIG. 7B. For example, in a case where the above-described first precursor, the above-described reactant, and the above-described catalyst are used, a SiO film as the stopper may be selectively grown on the first end surfaces 312. The above-described cycle is repeated a plurality of times until the stopper 314 grown from each of both the first end surfaces 312 exposed in the groove 350 is embedded between the first end surfaces 312. Accordingly, the stopper 314 is formed to be embedded between the first end surfaces 312.

### Removal Step

Next, after the film formation step, as illustrated in FIG. 7C, by supplying a removing agent to the wafer 200, the modified layer 324 formed on the second end surfaces 322 of the second film 320, which are exposed in the groove 350, is removed. That is, by supplying the removing agent reacting with the modified layer 324 as the inhibitor layer formed on the second end surfaces 322 of the wafer 200, the modified layer 324 is selectively removed.

Specifically, by opening the valve 273, the removing agent flows into the gas supply pipe 272. A flow rate of the removing agent is regulated by the MFC 271, and the removing agent is supplied into the process chamber 201 via the nozzle 249a and exhausted from the exhaust port 231a. At this time, from the side direction of the wafer 200, the removing agent is supplied to the wafer 200 (removing agent supply).

By supplying the removing agent to the wafer 200 under predetermined processing conditions (e.g., 500 degrees C. or higher), the modified layer 324 formed on the second end surfaces 322 may be removed. Further, as the removing agent, one or more of an O₃ gas plasma, an O₂ gas plasma, an anneal processing agent, and the like may be used.

### Second Film Formation Step

After the removal step is performed, as illustrated in FIG. 7D, by supplying the second film-forming agent to the wafer 200, a film with a composition different from that of the stopper 314 and identical to that of the second film 320 is formed in the groove 350 of the second film 320 of the wafer 200 to re-fill the groove 350. In addition, in the embodiments, an example in which, in this step, the groove 350 is re-filled by the film (i.e., the SiOC film) with the same composition as the second film 320 is described, but the present disclosure is not limited thereto. As long as the film is formed with a composition that is not subjected to etching when the third film 330, the first portion 311A of the first film 310, and the stopper 314 are removed in a post-process which is described later, the film may be used as a film for re-filling groove 350. For example, a film containing O and C may be appropriately used.

In the embodiments, in this step, a film with the same composition as the second film 320 is formed by the same sequence as the above-described first film formation step except that a precursor supplied is different. That is, the film is formed using, as the second film-forming agent, the second precursor (second precursor gas), the catalyst, and the reactant. Specifically, in the second film formation step, the SiOC film is formed using a Si precursor, containing C and halogen, as the second precursor different from the first precursor. By controlling the MFC 241e and the valve 243e in the second precursor supply system, the second precursor gas is supplied into the process chamber 201 via the nozzle 249b.

As the second precursor, for example, a Si-, C-, and halogen-containing gas may be used. The Si-, C-, and halogen-containing gas preferably contains C in a form of a Si—C bond. As the Si-, C-, and halogen-containing gas, for example, an alkylenechlorosilane-based gas containing an alkylene group may be used. The alkylene group includes a methylene group, an ethylene group, a propylene group, a butylene group, and the like. Further, as the Si-, C-, and halogen-containing gas, for example, an alkylchlorosilane-based gas containing an alkyl group may be used. The alkyl group includes a methyl group, an ethyl group, a propyl group, a butyl group, and the like.

As the second precursor, for example, bis(trichlorosilyl)methane ((SiCl₃)₂CH₂), 1,2-bis(trichlorosilyl)ethane ((SiCl₃)₂C₂H₄), 1,1,2,2-tetrachloro-1,2-dimethyldisilane ((CH₃)₂Si₂Cl₄), 1,2-dichloro-1,1,2,2-tetramethyldisilane ((CH₃)₄Si₂Cl₂), 1,1,3,3-tetrachloro-1,3-disilacyclobutane (C₂H₄Cl₄Si₂), and the like may be used. As the second precursor, one or more of these may be used.

An example of a processing sequence of the process of forming the film in this step may be represented as follows.

$$( Second precursor + catalyst \to reactant + catalyst ) \times n$$

In this step, a cycle including a precursor supply step of supplying the second precursor and the catalyst to the wafer 200 and a reactant supply step of supplying the reactant and the catalyst to the wafer 200 is repeated a plurality of times until the groove 350 is filled by a film

When the groove 350 is re-filled with the second film 320 in this step, in a case where mild film formation is performed, such as a case where plasma is not used, the above-described removal step of the modified layer 324 is preferably performed before re-filling. However, in a case where a film forming method using plasma is used in this step, e.g., a case where a plasma-excited gas such as O₂ plasma is used as the reactant, a case where a gas with a high energy state, such as O₃, is used, a case where this step is performed in a state in which the temperature of the wafer 200 is set to, for example, 300 degrees C. or higher (400 degrees C. or higher as an example with a more remarkable effect), and the like, the modified layer 324 may not act as a film formation inhibiting layer, and hence the above-described removal step may be omitted.

### After-Purge and Atmospheric Pressure Restoration

After the second film formation step is completed, an inert gas as a purge gas is supplied into the process chamber 201 from each of the nozzles 249a to 249c of the substrate processing apparatus 10 illustrated in FIG. 1 and exhausted from the exhaust port 231a. Accordingly, the interior of the process chamber 201 is purged, so that a gas, a reaction by-product, or the like, which remains in the process chamber 201, is removed from the interior of the process chamber 201. After that, the atmosphere in the process chamber 201 is replaced with the inert gas, so that the pressure in the process chamber 201 is restored to a normal pressure.

### Boat Unloading and Wafer Discharging

Next, the seal cap 219 is lowered by the boat elevator 115, so that the lower end of the manifold 209 is opened. Then, the processed wafers 200 are unloaded from the lower end of the manifold 209 to an outside of the reaction tube 203 in a state in which the processed wafers 200 are supported by the boat 217 (boat unloading). The processed wafers 200 are unloaded to the outside of the reaction tube 203 and then taken out of the boat 217.

Herein, the modification step and the first film formation step are preferably performed in the same process chamber (in-situ). Accordingly, it is possible to perform the modification step and the first film formation step without exposing the wafers 200 to the air, thus appropriately performing selective growth. That is, by performing these steps in the same process chamber, it is possible to perform the selective growth with high selectivity. Further, in a case where the removal step may be omitted as described above, the modification step, the first film formation step, and the second film formation step are performed in the same process chamber, so that it is possible to omit a time needed to load/unload the wafers 200.

### Post-Process

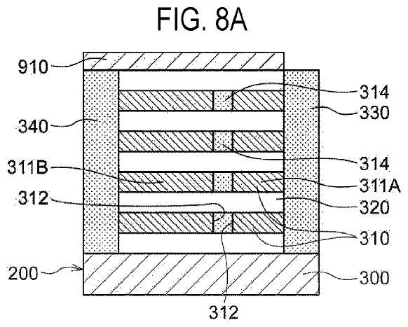

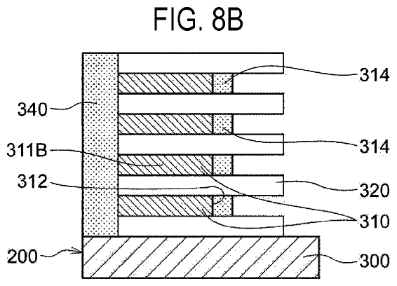

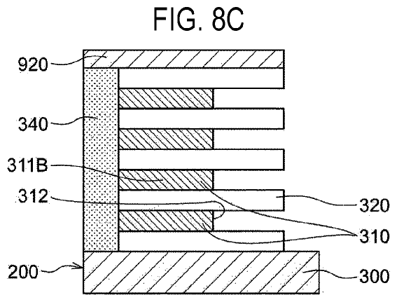

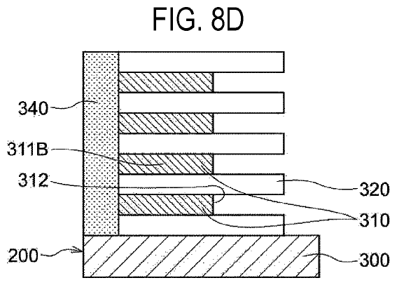

In the post-process, as illustrated in FIGS. 8A to 8D, the second portion 311B is left by removing the third film 330, the first portion 311A of the first film 310, and the stopper 314.

Specifically, as illustrated in FIG. 8A, a hard mask 910 is formed on the upper surface of the wafer 200 to cover at least the fourth film 340, and the third film 330 is removed through etching. Like the pre-process, as the etching, for example, anisotropic etching using a carbon fluoride (CF)-based gas plasma may be used. Also, the anisotropic etching may not be used.

Next, as illustrated in FIG. 8B, the first portion 311A of the first film 310 is removed up to the stopper 314 through etching. Specifically, in a state in which the fourth film 340, formed adjacent to side surfaces at which the second portion 311B of the first film 310 and the second film 320 are exposed, is left, the first portion 311A is etched from a side surface at which the first portion 311A is exposed, to be removed up to the stopper 314. That is, the first portion 311A is removed up to the stopper 314 from an end surface which is not covered with the second film 320.

At this time, the stopper 314 interrupts etching of the second portion 311B of the first film 310. As an etching agent (etching gas) used for etching the first film 310 which is the Si film, for example, at least one selected from the group of a fluorine (F)-based gas and a chlorine (Cl)-based gas may be used. For example, a fluorine (F₂) gas, a chlorine (Cl₂) gas, a chlorine trifluoride (ClF₃) gas, and the like may be used. Further, a gas (e.g., a hydrogen fluoride (HF) gas or the like) with an effect of etching an oxide film such as a SiO film or a SiOC film is not preferably used. Further, when etching the first portion 311A, an etching method exhibiting anisotropy is preferably used.

Next, as illustrated in FIG. 8C, by forming a hard mask 920 to cover the at least the fourth film 340, the stopper 314 of the first film 310 is removed through etching. Through the etching, the stopper 314, which is the SiO film, is selectively removed such that the second portion 311B of the first film 310, which is the Si film, and the second film 320, which is the SiOC film, are left. For example, as an etching method, dry etching or wet etching using an etching agent containing fluorine (F) may be used. As the etching agent, for example, a solution or gas containing hydrogen fluoride (HF) may be used. Then, the hard mask 920 is removed as illustrated in FIG. 8D.

In addition, the above-described etching processings in the post-process may be performed using different etching apparatuses, and it is also possible to perform the plurality of processings in the post-process by using the same etching apparatus.

### (3) Effects of Embodiments

According to the embodiments, one or more effects illustrated below are obtained.

The stopper 314 is formed in a portion of the first film 310 of the wafer 200, the first film 310 is divided into the first portion 311A and the second portion 311B, and the first portion 311A is removed up to the stopper 314. Thus, it is possible to remove a portion of the first film 310, i.e., the first portion 311A, with a high degree of precision and to leave the second portion 311B.

Further, by forming the groove 350 penetrating through the first film 310 and the second film 320 in the wafer 200, and supplying the first precursor (first film-forming agent) in the groove 350, at least a portion of the molecular structure of the molecules constituting the precursor is selectively deposited on the first end surfaces 312 of the first film 310, which are exposed in the groove 350, so that the stopper 314 is formed. Thus, it is possible to form the stopper 314 at a desired position of the first film 310 even with the configuration where the first film 310 is covered with the second film 320.

Further, the modified layer 324 inhibiting adsorption of the first precursor is selectively formed on the second end surfaces 322 of the second film 320, which are exposed in the groove 350. Thus, it is possible to suppress or prevent the stopper 314 from being formed on the second end surfaces 322 of the second film 320.

Further, after the modified layer 324 exposed in the groove 350 is removed, the second film 320 is formed in the groove 350 such that the groove 350 is re-filled. Thus, it is possible to avoid inhibition of the re-filling of the second film 320 by the modified layer 324.

Further, the second portion 311B is left by removing the stopper 314 after the first portion 311A of the first film 310 is removed. Thus, it is possible to leave the second portion 311B of the first film 310 with a high degree of precision.

Further, in the wafer 200, the second film 320 covers a periphery of the first film 310. Further, the other end surface of the second portion 311B of the first film 310 is covered with the fourth film 340. Thus, when etching the first portion 311A of the first film 310 and the stopper 314, it is possible to for the second film 320 to inhibit a circumferential surface of the first film 310, which is orthogonal to the length direction of the first film 310, from being etched and for the fourth film 340 to inhibit the other end surface of the second portion 311B from being etched.

Further, in the wafer 200, the plurality of first films 310 are formed at intervals in the second film 320. Thus, the groove 350 is formed in the wafer 200, so that it is possible to form the stopper 314 at the same position in the plurality of first films 310.

Further, the stopper 314 is formed at the same position in the first films 310 of the wafer 200 as described above, so that it is possible to identically remove the first portions 311A of the plurality of first films 310. Similarly, it is possible to identically align and leave the second portions 311B of the plurality of first films 310.

Further, in the wafer 200, the first film 310 is an oxygen-free film, and the second film 320 is an oxygen-containing film. Thus, it is possible to make an OH termination density of the second end surface 322 of the second film 320, which is the oxygen-containing film, larger than an OH termination density of the first end surface 312 of the first film 310, which is the oxygen-free film. Accordingly, it is possible to facilitate selective formation of the modified layer 324 by selectively reacting the modifying agent with the OH group at the second end surface 322 of the second film 320, which is exposed in the groove 350.

Further, the stopper 314 of the wafer 200 is an oxygen-containing film. Thus, it is possible to perform a function of an etching stopper film against the etching agent that exhibits an effect of etching an oxygen-free film when the first portion 311A of the first film 310, which is the oxygen-free film, is removed through etching.

Further, in the wafer 200, the first film 310 is configured as the Si film, the stopper 314 is configured as the SiO film, and the second film 320 is configured as the SiOC film. By using a combination of these, it is possible to leave the first film 310, which is the Si film, and the second film 320, which is the SiOC film, and selectively remove the stopper 314, which is the SiO film, through etching using HF.

Further, in the first film formation step and the second film formation step, the cycle in which the precursor supply step and the reactant supply step are alternately performed is performed a predetermined number of times, and the catalyst is supplied to the wafer 200 in at least one selected from the group of the precursor supply step and the reactant supply step, so that it is possible to perform selective growth with high controllability under the above-described low temperature condition.

### Other Embodiments of Present Disclosure

The embodiments of the present disclosure are described above in detail. However, the present disclosure is not limited to the above-described embodiments, and may be modified without departing from the spirit thereof.

### Another Embodiment 1

In another embodiment 1, components identical to those of the above embodiments are designated by the same reference numerals, and duplicate description is omitted or simplified.

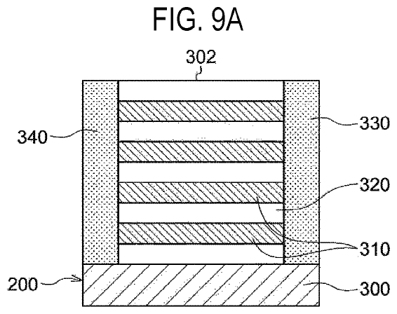

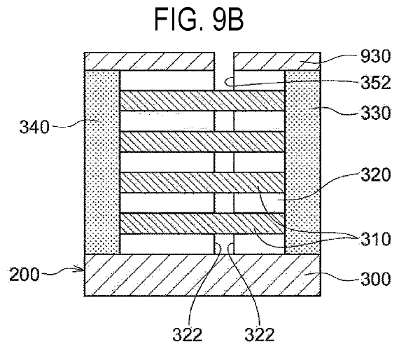

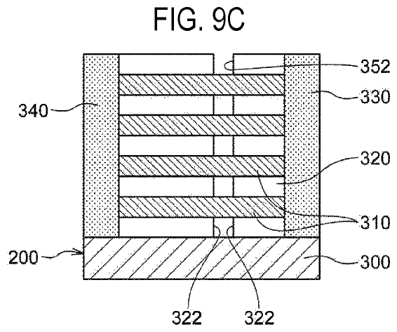

In a pre-process in the another embodiment 1, in the wafer 200 illustrated in FIG. 9A, a recess 352 is formed in the second film 320 such that a portion of the first film 310 is exposed as illustrated in FIG. 9B. Specifically, a hard mask 930 is formed on the upper surface of the wafer 200, and the second film 320 is selectively removed by etching to leave the first film 310 so that the recess 352 is formed. As the etching, for example, dry etching performed by supplying an etching gas to the wafer 200 may be used. Further, anisotropic etching, especially by gas plasma, may be suitably used. Further, as the etching gas, for example, a gas containing a halogen element, C, and H (hydrogen) may be used. For example, one or more of a hydrofluorocarbon (CHF₂) gas, a hydrochlorofluorocarbon (CHClF₂) gas, and the like, which are fluorocarbon-based gases containing H, may be used. Further, a mixed gas of a CF-based gas such as tetrafluorocarbon (CF₄) and a H-containing gas such as a H₂ gas may be used.

As illustrated in FIG. 9C, after the recess 352 is formed, the hard mask 930 is removed.

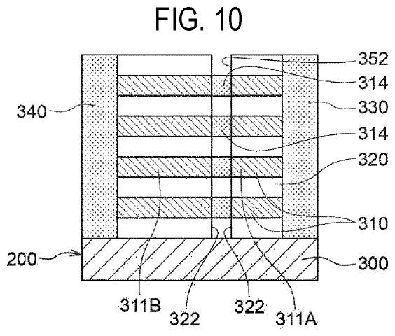

Next, as illustrated in FIG. 10, by supplying a second modifying agent to the wafer 200, a portion of the first film 310, which is exposed in the recess 352, is modified by the second modifying agent. The portion of the first film 310, which is modified by the second modifying agent, constitutes the stopper 314 (modification process). In this process, for example, a substrate processing apparatus which includes the same configuration as the substrate processing apparatus 10 and includes a second modifying agent supply system for supplying the second modifying agent instead of the modifying agent supply system may be used.

A portion of the first film 310 at one side of the stopper 314 is referred to as the first portion 311A, and a portion of the first film at the other side of the stopper 314 is referred to as the second portion 311B. From another viewpoint, a portion of the first film 310 is modified to be replaced with the stopper 314. Accordingly, the stopper 314 divides the first film 310 into the first portion 311A and the second portion 311B.

Further, the second modifying agent in this embodiment is an oxidizing agent, and the stopper 314 is an oxide film like the above-described embodiments. An oxidation rate of the first film 310, which is a Si film, by the oxidizing agent is larger than an oxidation rate of the second film 320, which is a SiOC film.

Therefore, for example, by supplying an O₃ gas, an O₂ gas plasma, a H₂+O₂ mixed gas plasma, or the like as the modifying agent (oxidizing agent) into the recess 352 or by supplying a H₂ gas and an O₂ gas as the modifying agent (oxidizing agent) under a condition of less than the atmospheric pressure, the portion of the first film 310, which is exposed in the recess 352, is selectively oxidized, so that the stopper 314 is formed.

In addition, a subsequent process is the same as the above-described embodiments. Specifically, processes after (second film formation process), and (post-process) are the same as the above-described embodiments.

In this embodiment, the same effects as the above-described embodiments are obtained. Further, in this embodiment, the stopper 314 is formed by modifying the portion of the first film 310, which is exposed in the recess 352, so that it is possible to simplify processes.

### Still Another Embodiment

For example, a second film formation step of, re-filling the groove 350 or the recess 352 with the second film 320 in the wafer 200 is included. However, the second film formation step may not be included. Meanwhile, the second film formation step is preferably included.

Further, for example, the first film 310 in the wafer 200 may be an oxygen-free film apart from the Si film, such as a nitrogen silicon film (SiN film), a metal-containing film, or the like. The second film 320 in the wafer 200 may be an oxygen-containing film apart from the SiOC film, such as a SiO film, a silicon oxycarbonitride film (SiOCN film), a metal oxide film, or the like.

Further, for example, the wafer 200 may include a plurality of regions made of different materials as the first film 310. Further, the wafer 200 may include a plurality of regions made of different materials as the second film 320.

The first film 310 and the second film 320 in the wafer 200 may use ones selected from the group including a semiconductor-containing film such as a silicon oxycarbonitride film (SiOCN film), a silicon oxycarbide film (SiOC film), a silicon oxynitride film (SiON film), a silicon carbonitride film (SiCN film), a silicon carbide film (SiC film), a silicon borocarbonitride film (SiBCN film), a silicon boronitride film (SiBN film), a silicon borocarbide film (SiBC film), a silicon film (Si film), a germanium film (Ge film) or silicon germanium film (SiGe film), a metal-containing film such as a titanium nitride film (TiN film), a tungsten film (W film), a molybdenum film (Mo film), a ruthenium film (Ru film), a cobalt film (Co film), a nickel film (Ni film) or a copper film (Cu film), an amorphous carbon film (a-C film), a monocrystalline Si wafer (Si wafer), and the like, in addition to the above-described combination of the Si film and the SiOC film.

Further, as the stopper 314, for example, a semiconductor-containing film such as a SiON film, a SiOCN film, a SiCN film, a SiC film, a SiN film, a SiBCN film, a SiBN film, a SiBC film, a Si film, a Ge film or a SiGe film, or a metal containing film such as a TiN film, a W film, a WN film, a Mo film, a Ru film, a Co film a Ni film, an Al film, an AlN film, a TiO film, a WO film, a WON film, a MoO film, a RuO film, a CoO film, a NiO film, an AlO film, a ZrO film, a HfO film or a TaO film may be formed in addition to the SiO film.

Further, as the stopper 314 and the second film 320, a film with a composition exhibiting a relative etching-resistance against an etching agent used when etching the first portion 311A of the first film 310 is selected. Further, as the first film 310 and the second film 320, a film with a composition exhibiting a relative etching-resistance against an etching agent used when etching the stopper 314 is selected. Further, as the first film 310 and the second film 320, ones of combinations of films with compositions where the modified layer (inhibitor layer) is relatively easily formed on a surface of the second film 320 as compared with a surface of the first film 310 may be selected. Even in a case where these films are used, the same effects as the above-described embodiments are obtained.

Preferably, a recipe used in each processing is individually prepared according to processing contents, and are recorded and stored in the memory 121c via an electrical communication line or the external memory 123. Further, preferably, when initiating each processing, the CPU 121a suitably selects an appropriate recipe according to the processing contents, among a plurality of recipes recorded and stored in the memory 121c.

In above-described embodiments, an example in which a film is formed using a batch-type substrate processing apparatus for processing a plurality of substrates at a time is described. The present disclosure is not limited to the above-described embodiments, and may be suitably applied even in a case where a film is formed using a single-wafer type substrate processing apparatus for processing one or several substrates at a time. Further, in the above-described embodiments, an example in which a film is formed using a substrate processing apparatus including a hot-wall type process furnace is described. The present disclosure is not limited to the above-described embodiments, and may be suitably applied even in a case where a film is formed using a substrate processing apparatus including a cold-wall type process furnace. Even in a case where theses substrate processing apparatuses are used, each processing may be performed in the same processing sequence and processing conditions as the above-described embodiments, and the same effects as the above-described embodiments or modifications are obtained.

The above-described embodiments may be suitably used in a combination thereof. Processing sequences and processing conditions at this time may be the same as, for example, the processing sequences and processing conditions of the above-described embodiments.

### INDUSTRIAL APPLICABILITY

According to the present disclosure in some embodiments, it is possible to, when etching a film in a substrate, remove a desired portion of the film with a high degree of precision.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) providing the substrate on which a first film and a second film covering the first film are formed, replacing a part of a portion of the first film, which is covered by the second film, with a stopper film, and dividing the first film into a first portion and a second portion by the stopper film; and
(b) leaving the second portion by removing the first portion which extends from an end surface of the first portion, which is not covered by the second film, to the stopper film.

2. The method of claim 1, wherein (a) further comprises:
(c) forming a groove penetrating through the second film and the portion of the first film, which is covered by the second film; and
(d) forming the stopper film by supplying a first precursor into the groove and depositing at least a portion of a molecular structure of molecules constituting the first precursor on an end surface of the first film, which is exposed in the groove.

3. The method of claim 2, wherein (a) further comprises:
before supplying the first precursor into the groove,
(e) forming a modified layer, suppressing deposition of the first precursor, on an end surface of the second film, which is exposed in the groove.

4. The method of claim 3, wherein, in (e), the modified layer is formed by adsorbing a modifying agent on the end surface of the second film, which is exposed in the groove.

5. The method of claim 4, wherein, in (e), the modifying agent is adsorbed by reacting the modifying agent with an OH group of the end surface of the second film, which is exposed in the groove.

6. The method of claim 2, further comprising:
before (b),
(f) filling the groove with the second film by supplying a second precursor into the groove.

7. The method of claim 6, wherein (a) further comprises:
before supplying the first precursor into the groove,
(e) forming a modified layer, suppressing deposition of the first precursor, on an end surface of the second film, which is exposed in the groove, and
wherein the method further comprises:
before (f),
(g) removing the modified layer formed on the end surface of the second film, which is exposed in the groove.

8. The method of claim 2, wherein, in the substrate, a third film is formed to cover the end surface of the first portion, which is not covered by the second film, and an end surface of the second film, and
wherein the method further comprises:
before (b),
(h) removing the third film.

9. The method of claim 8, wherein, in (b), the first portion is removed up to the stopper film by supplying an etching agent to the end surface of the first portion, which is exposed by removing the third film.

10. The method of claim 1, further comprising:
after (b),
(i) removing the stopper film.

11. The method of claim 2, wherein at least a portion of the first film is formed in the second film, such that the at least the portion of the first film is composed of a plurality of blocks formed at intervals in a direction orthogonal to a length direction.

12. The method of claim 2, wherein, in the substrate, a fourth film is formed to cover an end surface of the second portion, which is not covered by the second film, and an end surface of the second film, and
wherein, in (b), the first portion which extends from the exposed end surface of the first portion to the stopper film is removed through etching.

13. The method of claim 2, wherein the first film is an oxygen-free film, and the second film is an oxygen-containing film.

14. The method of claim 2, wherein compositions of the stopper film and the second film are different from each other.

15. The method of claim 2, wherein the first film is configured as a silicon film, the stopper film is configured as a silicon oxide film, and the second film is configured as a silicon oxycarbide film.

16. The method of claim 1, wherein (a) further comprises:
(j) forming a recess in the second film such that a portion of the first film is exposed; and
(k) modifying the portion of the first film, which is exposed in the recess, to the stopper film by supplying a second modifying agent into the recess.

17. A method of manufacturing a semiconductor device, comprising the method of claim 1.

18. A method of manufacturing a semiconductor device, comprising the method of claim 3.

19. A substrate processing apparatus comprising:
a first precursor supply system configured to supply a first precursor to a substrate;
a modifying agent supply system configured to supply a modifying agent to the substrate; and
a controller configured to capable of controlling the first precursor supply system and the modifying agent supply system to perform a process including:
supplying the modifying agent to the substrate in which a groove penetrating through a first film and a second film is formed, thereby forming a modified layer;
suppressing adsorption of the first precursor, on an end surface of the second film, which is exposed in the groove; and
supplying the first precursor into the groove and depositing at least a portion of a molecular structure of molecules constituting the first precursor on an end surface of the first film, which is exposed in the groove, thereby forming the stopper film of the method of claim 1.

20. A non-transitory computer-readable recording medium storing a program that causes, by a computer, a substrate processing apparatus to perform:
(a) supplying a modifying agent to a substrate in which a groove penetrating through a first film and a second film is formed, thereby forming a modified layer, suppressing adsorption of a first precursor, on an end surface of the second film, which is exposed in the groove; and
(b) supplying the first precursor into the groove and depositing at least a portion of a molecular structure of molecules constituting the first precursor on an end surface of the first film, which is exposed in the groove, thereby forming the stopper film of the method of claim 1.
